(19) United States
(12) Patent Application Publication
(10) Pub. No.: US 2025/0081387 A1
(43) Pub. Date: Mar. 6, 2025

(54) LIQUID-COOLING HEAT DISSIPATION DEVICE

(71) Applicant: JWS TECHNOLOGY CO., LTD., New Taipei City (TW)

(72) Inventors: Pang-Hung LIAO, New Taipei City (TW); Chih-Wei CHEN, New Taipei City (TW); Shih-Ming WANG, New Taipei City (TW)

(21) Appl. No.: 18/242,311

(22) Filed: Sep. 5, 2023

(51) Int. Cl. H05K 7/20

(52) U.S. Cl. CPC H05K 7/20236; H05K 7/20272; H05K 7/2039

(57) ABSTRACT

A liquid-cooling heat dissipation device includes a substrate, a fin assembly, a shell and a shunt component. The fin assembly is disposed on the substrate and has a plurality of channels parallelly arranged, and each of the channels has an inlet and an outlet opposite to each other. The shell is disposed on the substrate and has a liquid input port, a chamber is jointly formed by the shell and the substrate, and the chamber is located between the liquid input port and each of the inlets. The shunt component is disposed in the shell and has a plurality of manifold passages, the liquid input port is in communication with the chamber and each of the inlets through each of the manifold passages. Accordingly, the amount of fin member is increased in a fixed space to increase the heat dissipating efficiency.

### BACKGROUND OF THE DISCLOSURE

### Technical Field

The present disclosure relates to a heat dissipation device, especially to a liquid-cooling heat dissipation device used in an immersion liquid-cooling system and capable of increasing the heat dissipating efficiency.

### Description of Related Art

An immersion liquid-cooling system is to immerse a heat generating unit, such as a server, of an electronic device in a dielectric liquid (non-conductive liquid) disposed in a sealed machine case, thus heat generated by the heat generating unit is dissipated through a liquid property of the dielectric liquid. A related-art immersion liquid-cooling system is mainly categorized in two types: a single phase type and a dual phase type. The single phase type is to utilize a pump to push the dielectric liquid to generate a circulative flow, and a heat exchanger is used to achieve a heat dissipating effect. The dual phase type is that a dielectric liquid having a lower boiling point works with a condenser and the dielectric liquid constantly generates a phase change to achieve a heat dissipating effect.

No matter the single phase type or the dual phase type is adopted, the related-art immersion liquid-cooling system is to dispose a heat dissipation device having a plurality of fin members on a heat generating unit, thus the heat generated by the heat generating unit is rapidly transferred to each of the fin members to make the dielectric liquid perform a cooling effect. However, the gap between the fin members is limited and the dielectric liquid has a certain viscosity, thus the flow of the dielectric between each of the fin members of the heat dissipation device is poor, and the heat dissipating efficiency of the whole liquid-cooling system is greatly reduced.

As such, how to effectively increase the flow of the dielectric liquid between each of the fin members of the heat dissipation device, narrow the gap of the fin members in a fixed space to increase the disposing amount of the fin member, and greatly increase the heat dissipating efficiency of the heat dissipation device is the disadvantage to be improve.

Accordingly, the applicant of the present disclosure has devoted himself for improving the mentioned shortages.

### SUMMARY OF THE DISCLOSURE

The present disclosure is to provide a liquid-cooling heat dissipation device, the amount of fin member of a fin assembly is increased in a fixed space, meanwhile a dielectric liquid from a liquid input port evenly flows into each channel to greatly increase the heat dissipating efficiency.

Accordingly, the present disclosure provides a liquid-cooling heat dissipation device, which includes a substrate, a fin assembly, a shell and a shunt component. The fin assembly is disposed on the substrate and has a plurality of channels, each of the channels is parallelly arranged, and each of the channels has an inlet and an outlet opposite to each other. The shell is disposed on the substrate, covers each of the inlets, and has a liquid input port. A chamber is jointly formed by the shell and the substrate, and the chamber is located between the liquid input port and each of the inlets. The shunt component is disposed in the shell and has a plurality of manifold passages, the liquid input port is in communication with the chamber and each of the inlets through each of the manifold passages.

According to one embodiment of the present disclosure, the shunt component is disposed at an inner side of the shell and accommodated in the chamber.

According to one embodiment of the present disclosure, the shunt component has a connection plate and a plurality of block plates, each of the block plates is vertically connected at one lateral surface of the connection plate, and each of the block plates is arranged in a radiating manner from the liquid input port toward the fin assembly.

According to one embodiment of the present disclosure, a part of the block plates is respectively formed with a flow guiding inclined surface at one side toward the liquid input port.

According to one embodiment of the present disclosure, the shunt component has a plurality of convex parts and a plurality of concave parts, each of the convex parts and each of the concave parts are alternatively arranged to be formed in a wavy manner, and each of the manifold passages is enclosed by each of the convex parts and each of the concave parts.

According to one embodiment of the present disclosure, each of the convex parts is gradually expanded and extended from the liquid input port toward the fin assembly, and each of the concave parts is gradually expanded and extended from the liquid input port toward the fin assembly.

According to one embodiment of the present disclosure, the shunt component is disposed at an outer side of the shell and located between the liquid input port and the chamber.

According to one embodiment of the present disclosure, the shunt component has a pipe body and a plurality of partition walls, the pipe body is gradually expanded and extended from the liquid input port towards the chamber, and each of the partition walls is disposed in the pipe body to make each of the manifold passages be divided.

According to one embodiment of the present disclosure, each of the partition walls is respectively formed with a flow guiding inclined surface at one side of the liquid input port.

According to one embodiment of the present disclosure, the fin assembly has a plurality of fin members, and a volume of each of the manifold passages is positively related to an amount of the corresponding fin members.

Advantages achieved by the present disclosure are as follows. According to the liquid-cooling heat dissipation device provided by the present disclosure, the liquid input port is in communication with the chamber and the inlet of each of the channels through each of the manifold passages by the shunt component being disposed in the shell, and a width of the channel is narrowed in a fixed space to increase the amount of the fin member of the fin assembly, meanwhile the dielectric liquid from the liquid input port evenly flows into each of the channels through each of the manifold passages, thus the heat dissipating efficiency of the liquid-cooling heat dissipation device is greatly increased.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective view showing the assembly according to the first embodiment of the present disclosure;

FIG. 2 is another perspective view showing the assembly according to the first embodiment of the present disclosure;

FIG. 3 is a perspective view showing the shunt component according to the first embodiment of the present disclosure;

FIG. 4 is a top cross-sectional view according to the first embodiment of the present disclosure;

FIG. 5 is a side cross-sectional view according to the first embodiment of the present disclosure;

FIG. 6 is a side cross-sectional view showing an operating status according to the first embodiment of the present disclosure;

FIG. 7 is a perspective view showing the assembly according to the second embodiment of the present disclosure;

FIG. 8 is a perspective view showing the shunt component according to the second embodiment of the present disclosure;

FIG. 9 is a top cross-sectional view according to the second embodiment of the present disclosure;

FIG. 10 is a side cross-sectional view according to the second embodiment of the present disclosure;

FIG. 11 is a perspective view showing the assembly according to the third embodiment of the present disclosure;

FIG. 12 is another perspective view showing the assembly according to the third embodiment of the present disclosure;

FIG. 13 is a cross-sectional view showing the shunt component according to the third embodiment of the present disclosure; and

FIG. 14 is a top cross-sectional view according to the third embodiment of the present disclosure.

### DETAILED DESCRIPTION OF THE DISCLOSURE

It is to be understood that the terms for indicating positions and the location relation, for example “front”, “rear”, “left”, “right”, “front end”, “rear end”, “distal end”, “vertical”, “horizontal”, “top end” and “bottom end”, are based on the positions and the location relation disclosed in the drawings, and only used for disclosing the present disclosure and not used for indicating or implying the specified location of the device or the components or the specified structure and operation in certain location, thus the present disclosure is not intended to be limiting.

The technical contents of this disclosure will become apparent with the detailed description of embodiments accompanied with the illustration of related drawings as follows. It is intended that the embodiments and drawings disclosed herein are to be considered illustrative rather than restrictive.

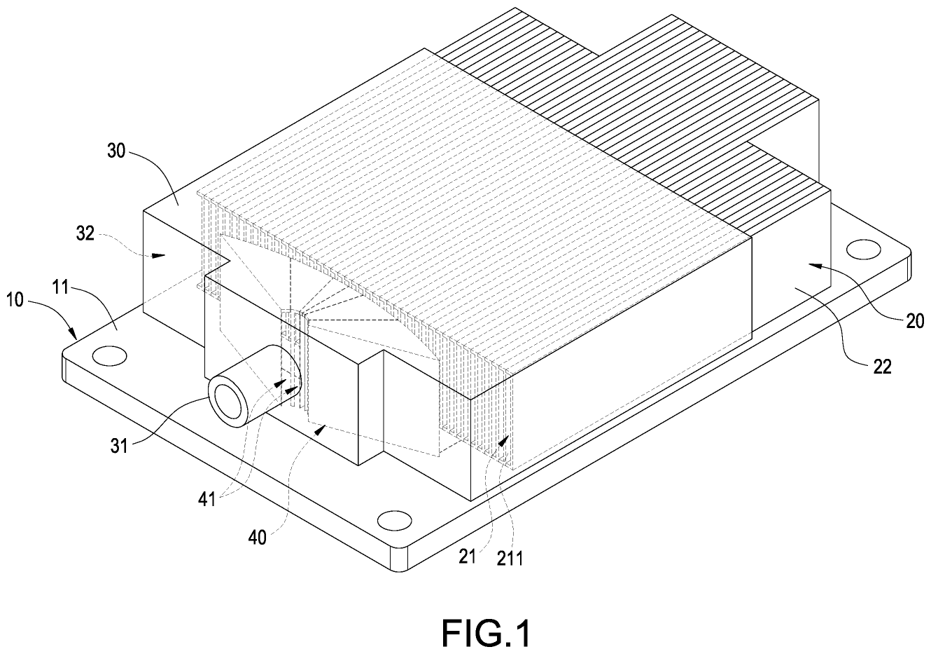

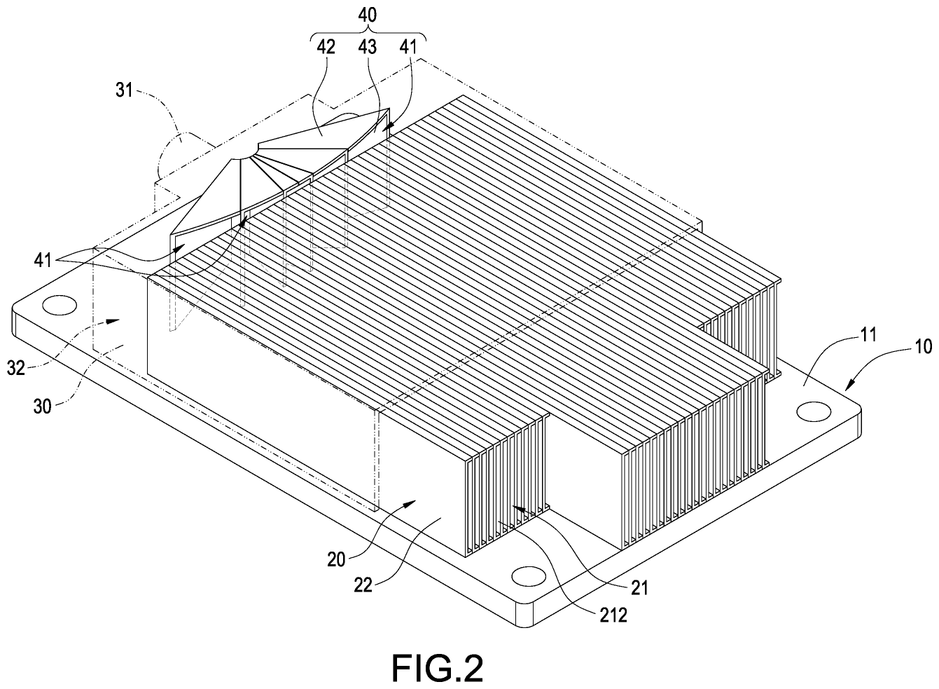

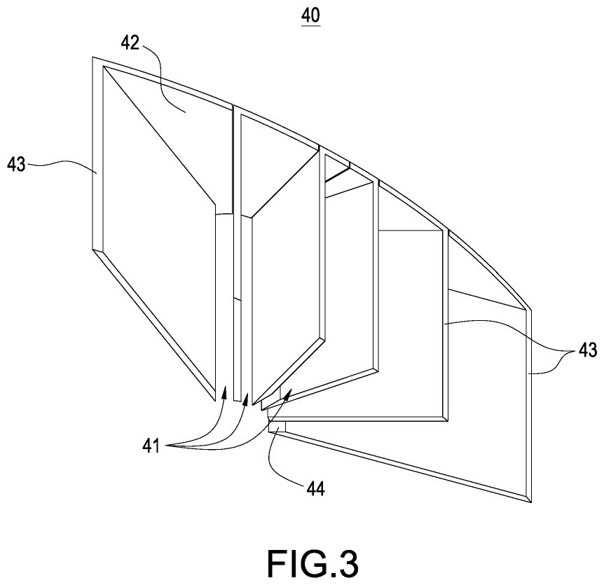

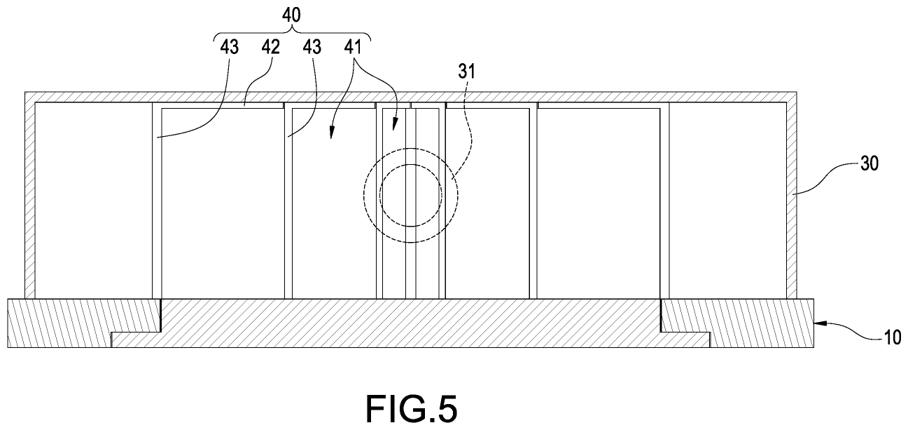

The present disclosure provides a liquid-cooling heat dissipation device, which is used in an immersion liquid-cooling system, and attached on a heat generating unit B immersed in a dielectric liquid A, thus heat generated by the heat generating unit B is exchanged to the dielectric liquid A to achieve a heat dissipating effect. Please refer from FIG. 1 to FIG. 5, and according to the first embodiment of the present disclosure, the liquid-cooling heat dissipation device includes a substrate 10, a fin assembly 20, a shell 30 and a shunt component 40.

The substrate 10 is made of a material having a desirable heat conductivity, for example aluminum, copper, gold, tungsten, or an alloy thereof, here is not intended to be limiting. In some embodiments, the substrate 10 is formed in a rectangular plate shape, but the shape of the substrate 10 may be correspondingly adjusted with respect to the shape and dimension of the heat generating unit B or other requirements, here is not intended to be limiting. The substrate 10 has an attaching surface (not labelled in figures) and an installing surface 11 opposite to the attaching surface. The attaching surface is used to be attached on the heat generating unit B, thus the substrate 10 may rapidly absorb the heat generated by the heat generating unit B through the attaching surface.

The fin assembly 20 is disposed on the installing surface 11 of the substrate 10. The fin assembly 20 is made of a material having a desirable heat conductivity, for example aluminum, copper, gold, tungsten, or an alloy thereof, here is not intended to be limited. The fin assembly 20 has a plurality of channels 21. Each of the channels 21 are parallelly arranged, and each of the channels 21 has an inlet 211 and an outlet 212 opposite to each other. In some embodiments, the fin assembly 20 includes a plurality of fin members 22 formed as “[” shape through a punching formation manner. Each of the fin members 22 is oriented toward the same direction and sequentially soldered and fastened to form the fin assembly 20. The fin assembly 20 of the present disclosure is limited to aforementioned embodiments. The shape and the fastening manner of each of the fin members 20 may be altered in other embodiments. Moreover, the shape, the amount, the arranging and the combining manner of the fin members 22 of the fin assembly 20 of the present disclosure are not intended to be limiting.

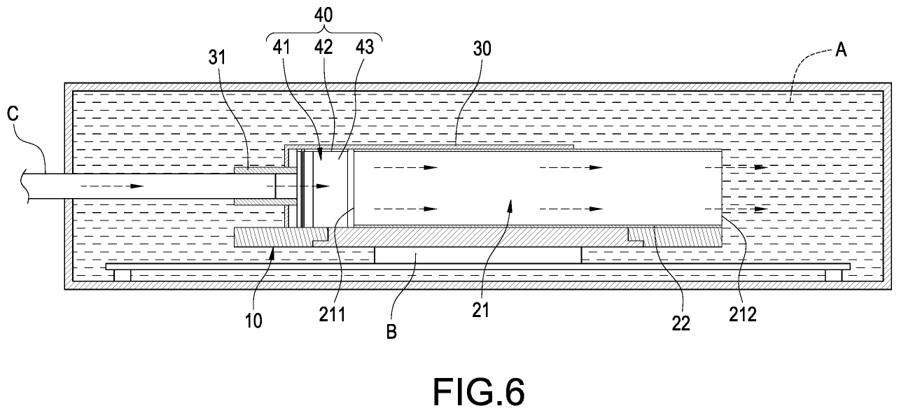

The shell 30 is disposed on the installing surface 11 of the substrate 10. The shell 30 at least covers each of the inlets 211 of the fin assembly 20. As such, the shell 30 may cover the whole fin assembly 20. In some embodiments, the shell 30 is made of a metal material, a plastic material or other materials. A front surface of the shell 30 has a liquid input port 31. The liquid input port 31 is substantially formed in a hollow pipe manner, thus the liquid input port 31 is connected to a soft pipe C of a pump (not shown in figures) as shown in FIG. 6. The liquid input port 31 and the shell 30 may be formed in one piece, or the liquid input port 31 and the shell 30 are two components which are combined and fastened. A chamber 32 is jointly formed by an inner side of the shell 30 and the installing surface 11 of the substrate 10, and the chamber 32 is located between the liquid input port 31 and each of the inlets 211.

The shunt component 40 is disposed in the shell 30, and the disposing manner is illustrated below. The shunt component 40 has a plurality of manifold passages 41. The liquid input port 31 is in communication with the chamber 32 and each of the inlets 211 through each of the manifold passages 41. As shown in FIG. 6, the dielectric liquid A pushed by the pump to enter the liquid input port 31 from the soft pipe C is shunted to the chamber 32 from each of the manifold passages 41 and pass each of the inlets 211 to flow into the fin assembly 20 through the soft pipe C directly communicating with the liquid input port 31, thus the dielectric liquid A evenly passes each of the channels 21 of the fin assembly 20 to force the dielectric liquid A to flow through each of the fin members 22 for performing the heat exchange to achieve a desirable heat dissipating effect, and a gap between the fin members 22 is decreased in a fixed space of the liquid-cooling heat dissipation device, meanwhile the arranging amount of the fin member 22 is increased to enhance the heat dissipating efficiency.

Details are provided as follows. In some embodiments, the shunt component 40 is disposed at the inner side of the shell 30 and accommodated in the chamber 32 as shown from FIG. 1 to FIG. 5. In some embodiments, the shunt component 40 is soldered at the inner side of the shell 30. The shunt component 40 includes a connection plate 42 and a plurality of block plates 43. The connection plate 42 is substantially formed in a fan shape. Each of the block plates 43 is vertically connected at a bottom surface of the connection plate 42. Each of the block plates 43 is arranged in a radiating manner from the liquid input port 31 toward the fin assembly 20. In some embodiments, there are six block plates 43, the connection plate 42 is correspondingly divided into six pieces for a purpose of being easily manufactured, and a soldering operation is processed to form the shunt component 40, here is not intended to be limiting. For example, the shunt component 40 may be formed in one piece or divided into other shapes and combined and fastened after being manufactured.

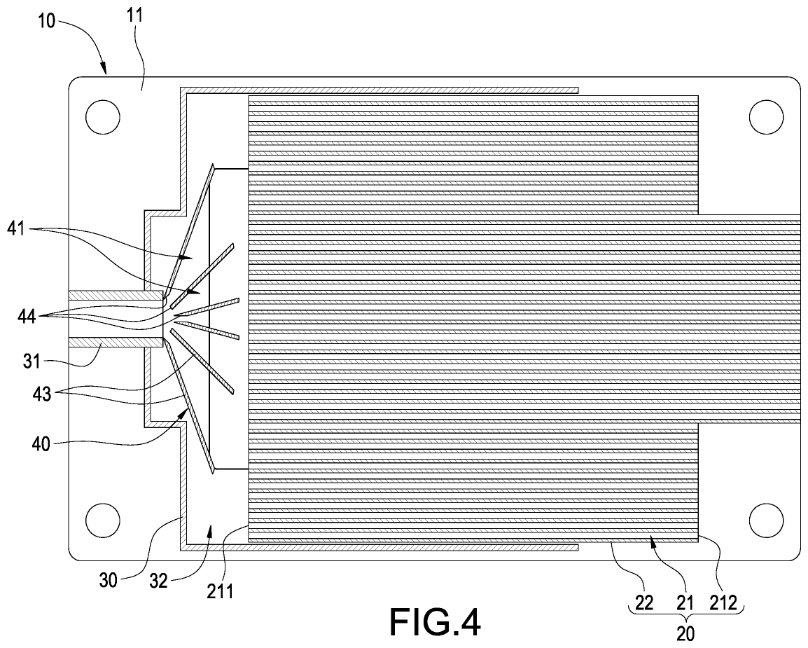

Please refer to FIG. 4, a part of the block plates 43 is respectively formed with a flow guiding inclined surface 44 at one side toward the liquid input port 31, and each of the flow guiding inclined surfaces 44 is arranged toward the central axial line of the liquid input port 31. In some embodiments, each of the flow guiding inclined surfaces 44 is respectively disposed at two of the block plates 43 arranged at the outmost sides and two of the block plates 43 at the inmost sides, thus the caliber of the manifold passage 41 at the inlet 211 is increased, and the flow of the dielectric liquid A is prevented from being affected due to the overly large resistance generated when the dielectric liquid A flows in each of the manifold passages 41 from the liquid input port 31, meanwhile an effect of guiding the dielectric liquid A to smoothly flow is also provided.

Details are provided as follows. In some embodiments, the volume of each of the manifold passages 41 is positively related to the amount of the corresponding fin members 22 (that is, positive correlation). Substantially speaking, because each of the manifold passages 41 is enclosed by two of the block plates 43 and the connection plate 42, under a situation of the amount of the fin member 22 and the size of the shunt component 40 of the liquid-cooling heat dissipation device being fixed, a ratio of the volume of any of the manifold passages 41 and the summed volume of all of the manifold passages 41 has to be the same or similar to a ratio of the amount of the fin member 22 corresponding to the manifold passage 41 and the total amount of the fin member 22. In other words, the greater the included angle formed by the two block plates 43 of any of the manifold passages 41, the greater the amount of the corresponding fin members 22. As such, the dielectric liquid A is ensured to evenly flow into each of the channels 21 of the fin assembly 20 after the dielectric liquid A is shunted by the shunt component 40.

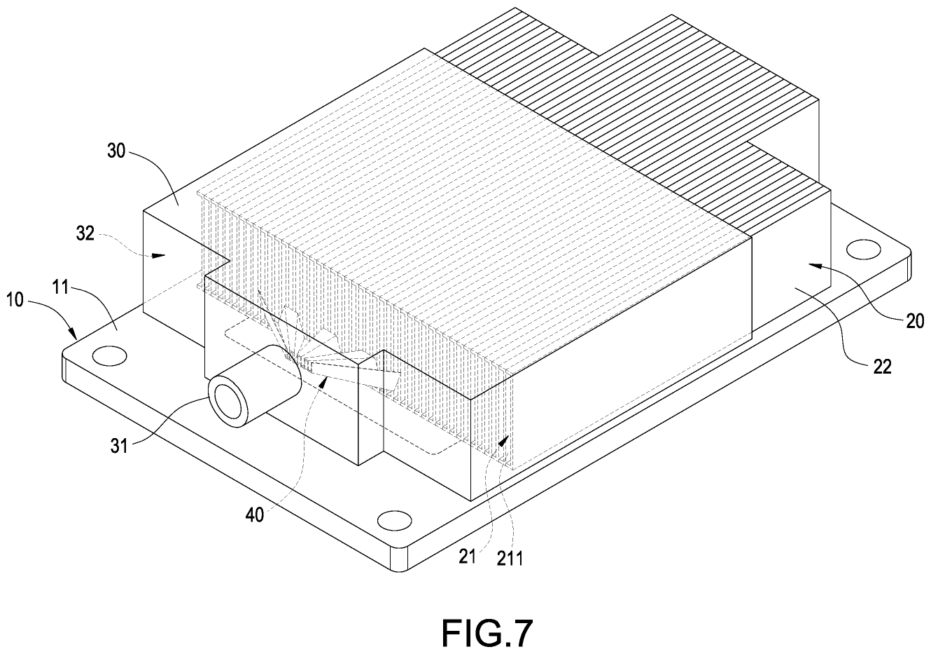

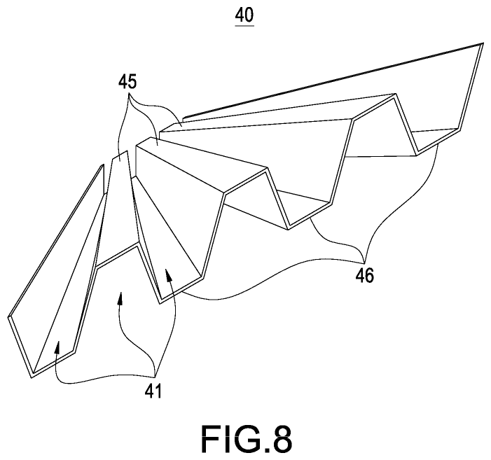

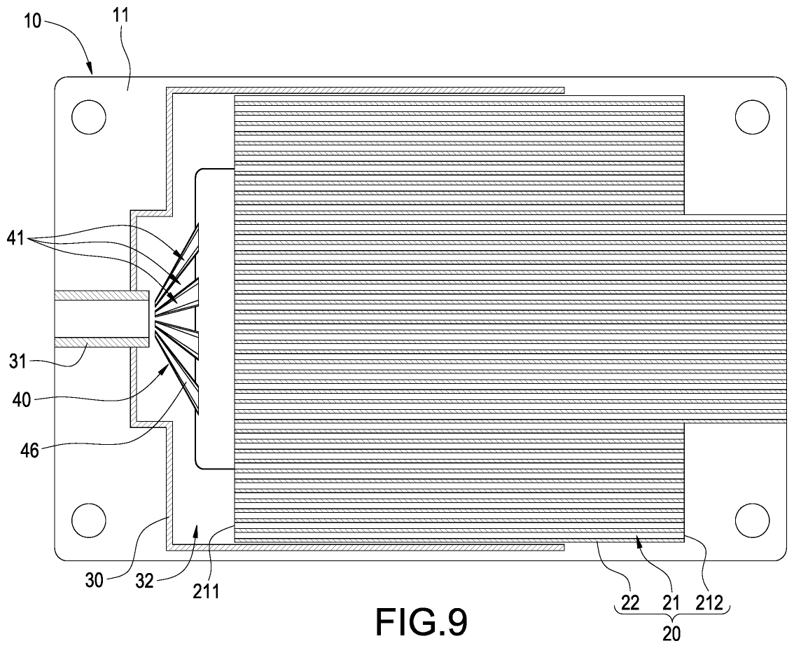

Please refer from FIG. 7 to FIG. 10, which disclose the second embodiment of the present disclosure. A main difference between the second embodiment and the first embodiment is the structure of the shunt component 40, thus the same arrangement is omitted here for brevity and the differences are provided as follows.

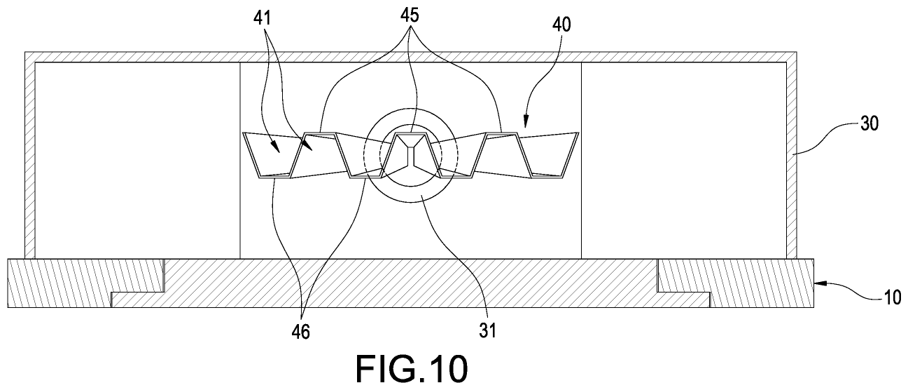

In some embodiments, the shunt component 40 is bent and formed in one piece. The shunt component 40 includes a plurality of convex parts 45 and a plurality of concave parts 46. Each of the convex parts 45 and each of the concave parts 46 are alternatively arranged to be formed in a wavy manner. Each of the manifold passages 41 is enclosed by each of the convex parts 45 and each of the concave parts 46, in other words, each of the manifold passages 41 is sequentially disposed on a top end or a bottom end of the shunt component 40 with a manner of being arranged from left to right. Each of the convex parts 45 is gradually expanded and extended from the liquid input port 31 toward the fin assembly 20. Each of the concave parts 46 is gradually expanded and extended from the liquid input port 31 toward the fin assembly 20. As such, the shunt component 40 is in a trapezoid shape while being viewed from the top, as shown in FIG. 10.

Accordingly, each of the manifold passages 41 is respectively disposed at the top side and the bottom side of the shunt component 40, thus the amount of the manifold passage 41 is increased with respect to the first embodiment of the present disclosure, and the shunting effect is further enhanced. It is to be understood that the amount of the manifold passage 41 shown in figures of the present disclosure is served as examples to make the skilled people in the art easily understand, here is not intended to be limiting.

In some embodiments, the volume of each of the manifold passages 41 is positively related to the amount of the corresponding fin members 22 (that is, positive correlation). Substantially speaking, because each of the manifold passages 41 is formed the convex part 45 or the concave part 46, under a situation of the amount of the fin member 22 and the size of the shunt component 40 of the liquid-cooling heat dissipation device being fixed, a ratio of the volume of any of the manifold passages 41 and the summed volume of all of the manifold passages 41 has to be the same or similar to a ratio of the amount of the fin member 22 corresponding to the manifold passage 41 and the total amount of the fin member 22. In other words, the greater the included angle formed by convex part 45 or the concave part 46 of any of the manifold passages 41, the greater the amount of the corresponding fin member 22. As such, the dielectric liquid A is ensured to evenly flow into each of the channels 21 of the fin assembly 20 after the dielectric liquid A is shunted by the shunt component 40.

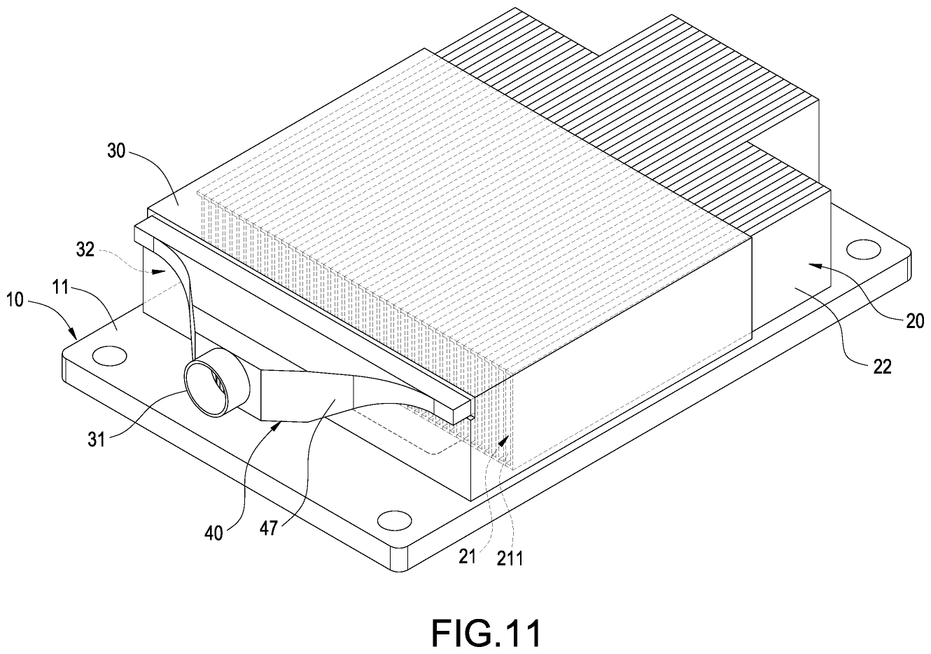

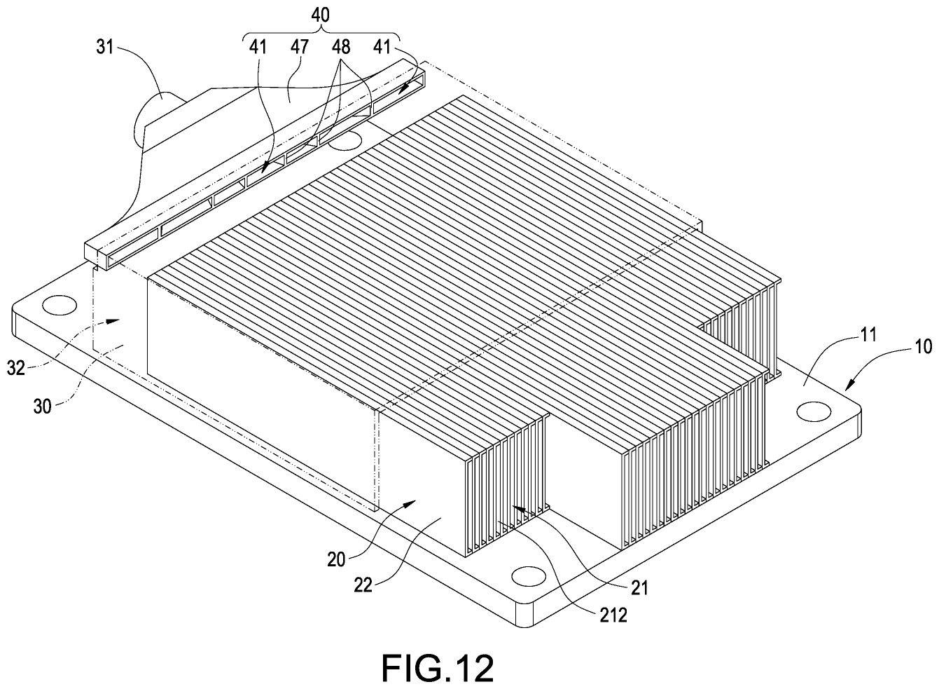

Please refer from FIG. 11 to FIG. 14, which disclose the third embodiment of the present disclosure. Main differences between the third embodiment and the first embodiment are the structure and the disposed location of the shunt component 40, thus the same arrangement is omitted here for brevity and the differences are provided as follows.

In some embodiments, the shunt component 40 is disposed at an outer side of the shell 30, and located between the liquid input port 31 and the chamber 32. Substantially speaking, the shunt component 40 is soldered at the outer side of the shell 30. The shunt component 40 includes a pipe body 47 and a plurality of partition walls 48. The pipe body 47 is gradually expanded and extended from the liquid input port 31 toward the chamber 32 to be formed as a trapezoid manner. Each of the partition walls 48 is disposed in the pipe body 47 to partition an inner space of the pipe body 47 to form each of the manifold passages 41. In some embodiments, the shunt component 40 and the liquid input port 31 are formed in one piece through a plastic injecting or a metal casting manner and disposed in the shell 30, here is not intended to be limiting. For example, the shunt component 40, the liquid input port 31 and the shell 30 may be directly formed in one piece through the plastic injecting or the metal casting manner, or the shunt component 40 and the shell 30 are firstly formed in one piece through the plastic injecting or the metal casting manner and then the liquid input port 31 is disposed at a front end of the shunt component 40.

Accordingly, the shunt component 40 is directly connected between the liquid input port 31 and the chamber 32, thus the dielectric liquid A flowing in the liquid input port 31 is completely shunted by the shunt component 40 and enters the chamber 32 and then enters each of the inlets 211, and a better shunting effect is effectively provided with respect to the first embodiment.

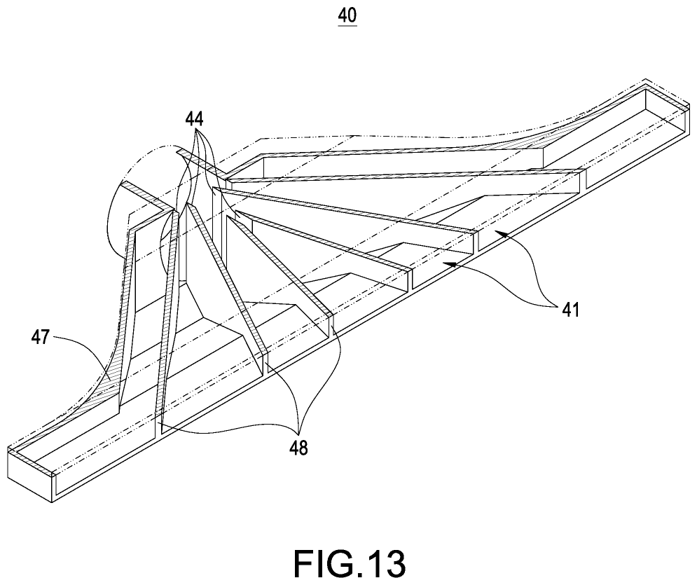

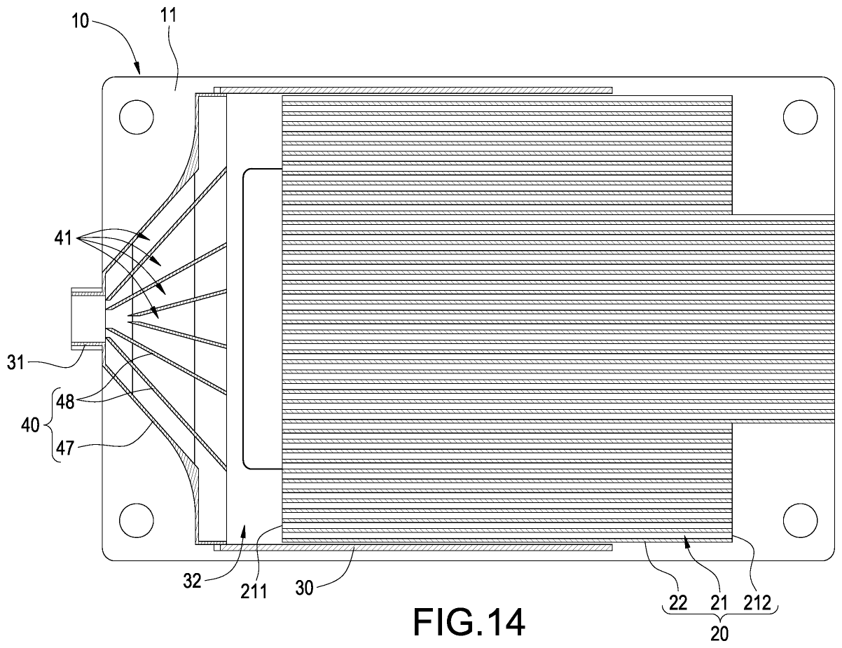

Please refer to FIG. 13 and FIG. 14. In some embodiments, each of the partition walls 48 is respectively formed with a flow guiding inclined surface 44 at one side of the liquid input port 31. Each of the flow guiding inclined surfaces 44 is arranged toward the central axial line of the liquid input port 31. As such, the caliber of the manifold passage 41 at the inlet 211 is increased, and the flow of the dielectric liquid A is prevented from being affected due to the overly large resistance generated when the dielectric liquid A flows in each of the manifold passages 41 from the liquid input port 31, meanwhile an effect of guiding the dielectric liquid A to smoothly flow is also provided.

In some embodiments, the volume of each of the manifold passages 41 is positively related to the amount of the corresponding fin member 22 (that is, positive correlation). Substantially speaking, because each of the manifold passages 41 is formed through the pipe body 47 and at least one of the partition walls 48, under a situation of the amount of the fin member 22 and the size of the shunt component 40 of the liquid-cooling heat dissipation device being fixed, a ratio of the volume of any of the manifold passages 41 and the summed volume of all of the manifold passages 41 has to be the same or similar to a ratio of the amount of the fin member 22 corresponding to the manifold passage 41 and the total amount of the fin member 22. In other words, the greater the volume of any of the manifold passages 41, the greater the amount of the corresponding fin members 22. As such, the dielectric liquid A is ensured to evenly flow into each of the channels 21 of the fin assembly 20 after the dielectric liquid A is shunted by the shunt component 40.

According to the heat dissipation device of the present disclosure, the liquid input port 31 is in communication with the chamber 32 and the inlet 211 of each of the channels 21 through each of the manifold passages 41 through the shunt component 40 being disposed in the shell 30, and a width of the channel 21 is narrowed in a fixed space to increase the amount of the fin member 22 of the fin assembly 20, meanwhile the dielectric liquid A from the liquid input port 31 evenly flows into each of the channels 21 through each of the manifold passages 41, thus the heat dissipating efficiency of the liquid-cooling heat dissipation device is greatly increased.

While this disclosure has been described by means of specific embodiments, numerous modifications and variations could be made thereto by those skilled in the art without departing from the scope and spirit of this disclosure set forth in the claims.

What is claimed is:

1. A liquid-cooling heat dissipation device, comprising:
a substrate;
a fin assembly, disposed on the substrate and comprising a plurality of channels, wherein the channels are parallelly arranged, and each of the channels has an inlet and an outlet opposite to each other;
a shell, disposed on the substrate, covering a plurality of inlets, and comprising a liquid input port, wherein a chamber is jointly defined by the shell and the substrate, and the chamber is located between the liquid input port and each of the inlets; and
a shunt component, disposed in the shell and comprising a plurality of manifold passages, wherein the liquid input port is in communication with the chamber and each of the inlets through each of the manifold passages.

2. The liquid-cooling heat dissipation device according to claim 1, wherein the shunt component is disposed inside the shell and accommodated in the chamber.

3. The liquid-cooling heat dissipation device according to claim 2, wherein the shunt component comprises a connection plate and a plurality of block plates, each of the block plates is vertically connected to a lateral surface of the connection plate, and each of the block plates is arranged in a radiating manner from the liquid input port toward the fin assembly.

4. The liquid-cooling heat dissipation device according to claim 3, wherein a flow guiding inclined surface is disposed on a part of the block plates at one side thereof toward the liquid input port.

5. The liquid-cooling heat dissipation device according to claim 3, wherein the shunt component comprises a plurality of convex parts and a plurality of concave parts, each of the convex parts and each of the concave parts are alternatively arranged in a wavy manner, and each of the manifold passages is enclosed by each of the convex parts and each of the concave parts.

6. The liquid-cooling heat dissipation device according to claim 5, wherein each of the convex parts is gradually expanded and extended from the liquid input port toward the fin assembly, and each of the concave parts is gradually expanded and extended from the liquid input port toward the fin assembly.

7. The liquid-cooling heat dissipation device according to claim 1, wherein the shunt component is disposed outside the shell and located between the liquid input port and the chamber.

8. The liquid-cooling heat dissipation device according to claim 7, wherein the shunt component comprises a pipe body and a plurality of partition walls, the pipe body is gradually expanded and extended from the liquid input port toward the chamber, and the manifold passages are divided by the partition walls disposed in the pipe body.

9. The liquid-cooling heat dissipation device according to claim 8, wherein a flow guiding inclined surface is disposed on each of the partition walls at one side thereof toward the liquid input port.

10. The liquid-cooling heat dissipation device according to claim 1, wherein the fin assembly comprises a plurality of fin members, and a volume of each of the manifold passages is positively related to an amount of the fin members.
